(19) United States
(12) Patent Application Publication
(10) Pub. No.: US 2008/0149179 A1
(43) Pub. Date: Jun. 26, 2008

(54) Process for Large-Scale Production of Cdte/Cds Thin Film Solar Cells, Without the Use of Cdci2

(76) Inventors: Nicola Romeo, Parma (IT); Alessio Bosio, Parma (IT); Alessandro Romeo, Parma (IT)

Correspondence Address: POLLACK, P.C., THE CHRYSLER BUILDING, 132 EAST 43RD STREET, SUITE 760, NEW YORK, NY, 10017, US

(21) Appl. No.: 11/884,055

(22) PCT Filed: Feb. 2, 2006
(86) PCT No.: PCT/IT06/00053

§ 371 Date: Aug. 8, 2007

(30) Foreign Application Priority Data
Feb. 8, 2005 (IT) LU2005A000002

(51) Int. Cl. H01L 31/18; B05D 5/12

(52) U.S. Cl. 136/264; 427/74; 427/76

(57) ABSTRACT

A process for large-scale production of CdTe/CdS thin film solar cell the films of the solar cells being deposited as a sequence on a transparent substrate, which comprises the steps of: depositing a film of a transparent conductive oxide (TCO) on the substrate; depositing a film of CdS on the TCO film; treating the CdTe film with Chlorine-containing inert gas; and depositing a back-contact film on the treated CdTe film. The Chlorine-containing inert gas is a Chlorofluorocarbon or a Hydrochlorofluorocarbon product and the treatment is carried out in a vacuum chamber at an operating temperature of 380-420° C. The Chlorine released as a result of the thermal dissociation of the product reacts with solid CdTe present on the cell surface to produce TeCl₂ and CdCl₂ vapors. Any residual CdCl₂ is removed from the cell surface by applying a vacuum to the vacuum chamber while keeping the temperature at the operating value.

### FIELD OF THE INVENTION

The present invention relates to the field of the solar cells technology and more particularly concerns a process for the large-scale production of CdTe/CdS thin film solar cells. In particular, the invention relates to an improvement to this process relating to the activation of the CdTe/CdS thin-film by means of chlorine containing gas. Even if in the present specification reference is made to “CdTe/CdS thin-film” solar cells for sake of simplicity, it is to be understood that this term includes all the salt mixtures comprised in the formula

ZnₓCd₁₋ₓS/CdTe_{y}S_{1-y}

wherein 0≦x≦0.2 e 0.95≦y≦1.

### BACKGROUND ART OF THE INVENTION

As is known, a typical configuration of a CdTe/CdS solar cell has a film sequence of the multi-layer arrangement comprising a transparent glass substrate carrying a transparent conductive oxide (TCO) film, a CdS film representing the n-conductor, a CdTe film representing the p-conductor and a metallic back-contact. A solar cell with a layer arrangement and structure of this type is disclosed, for example, in U.S. Pat. No. 5,304,499.

The commercial float glass may be used as a transparent substrate, but, in spite of its low cost, special glasses are often preferred to avoid drawbacks of the float glass, in particular Na diffusion into TCO film.

The most common TCO is In₂O₃ containing 10% of Sn (ITO). This material has a very low resistivity on the order of 3×10⁻⁴ Ωcm and high transparency (>85%) in the visible spectrum. However, this material is made by sputtering and the ITO target after several runs forms some noodles which contain an In excess and a discharge between noodles can happen during sputtering which can damage the film. Another material which is commonly used is fluorine doped SnO₂ which however exhibits a higher resistivity close to 10⁻³ Ωcm and as a consequence a 1 μm thick layer is needed in order for the sheet resistance to be around 10Ω/_{square}. A high TCO thickness decreases the transparency and then the photocurrent of the solar cell. The use of Cd₂SnO₄ has also been proposed by the NREL group (X. Wu et al., Thin Solid Films, 286 (1996) 274-276). Also this material has some drawbacks since the target is made up of a mixture of CdO and SnO₂ and, being CdO highly hygroscopic, the stability of the target may result to be unsatisfactory.

WO03/032406, in the name of the same applicant, discloses a process for large-scale production of CdTe/CdS thin-film solar cells in which the deposition of the TCO film is conducted in such a way that a film of very low resistivity can be deposited without formation of any metal noodles on the target and allowing the use of a inexpensive substrate. To this end, the TCO layer is formed by sputtering in an inert gas atmosphere containing hydrogen, or an argon-hydrogen mixture, and a gaseous fluoralkyle compound, e.g. CHF₃. In this way the TCO is doped with fluorine.

The CdS film is deposited by sputtering or Close-Spaced Sublimation (CSS) from CdS granulate material. This last technique allows the preparation of thin films at a substrate temperature much higher than that used in simple vacuum evaporation or sputtering, because substrate and evaporation source are put very close to each other at a distance of 2-6 mm and the deposition is done in the presence of an inert gas such as Ar, He or N₂ at a pressure of 10⁻¹-100 mbar. A higher substrate temperature allows the growth of a better crystalline quality material. An important characteristic of the close-spaced sublimation is a very high growth rate up to 10 μm/min, which is suitable for large-scale production.

CdTe film is deposited on top of CdS film by close-spaced sublimation (CSS) at a substrate temperature of 480-520° C. CdTe granulate is generally used as a source of CdTe which is evaporated from an open crucible.

The electric back contact on the CdTe film is generally obtained by deposition of a film of a highly p-dopant metal for CdTe such as copper, e.g. in graphite contacts, which, upon annealing, can diffuse in the CdTe film. The use of a Sb₂Te₃ film as a back-contact in a CdTe/CdS solar cell has been disclosed by the same applicants (N. Romeo et al., A highly efficient and stable CdTe/CdS thin film solar cell, Solar Energy Materials & Solar Cells, 58 (1999), 209-218).

An important step in the preparation of high efficiency CdTe/CdS solar cells is the activation treatment of CdTe film. Most research groups use to carry out this step by depositing on top of CdTe a layer of CdCl₂ by simple evaporation or by dipping CdTe in a methanol solution containing CdCl₂ and then anneal the material in air at 400° C. for 15-20 min. To avoid the first step described above, it has been recently proposed to use vapor CdCl₂ to treat CdTe (C. S. Ferekides et al., CdTe thin film solar cells: device and technology issue, Solar Energy, 77, (2004), 823-830; B. E. McCandless et al., Processing options for CdTe thin film solar cells, Solar Energy, 77, (2004), 839-856). In this case the vapor of CdCl₂ is obtained by a source facing the CdTe film or conveyed from a remote source by a carrier gas. The use of HCl has also been proposed as an alternative to the CdCl₂ treatment. (T. X. Zhou et al., Vapor chloride treatment of polychrystalline CdTe/CdS films, Proceedings of the 1^{st} WCPEC, 1994) It is generally believed that the CdCl₂ treatment improves the crystalline quality of CdTe by increasing the size of small grains, improving the mixing between CdS and CdTe and removing several defects in the material.

In any case, after CdCl₂ treatment, CdTe has to be etched in a solution of Br-methanol or in a mixture of nitric and phosphoric acid. Etching is necessary as CdO or CdTeO₃ are generally formed on the CdTe surface. CdO and/or CdTeO₃ have to be removed in order to make a good back contact onto CdTe. Besides it is believed that, since etching produces a Te-rich surface, the formation of an ohmic contact when a metal is deposited on top of CdTe is facilitated.

To avoid the etching treatment of the CdTe film and allow the production process to be carried out in a continuous way, WO03/032406 suggests to treat the CdTe film with CdCl₂ by first forming a 100-200 nm thick layer of CdCl₂ on the CdTe film by evaporation, while keeping the substrate at room temperature; then annealing the CdCl₂ layer in a vacuum chamber at 380-420° C. and 300-1000 mbar under inert gas atmosphere; and finally removing the inert gas from said chamber to produce vacuum condition, while the substrate is kept to a temperature of 350-420° C., whereby any residual CdCl₂ is evaporated from the CdTe film surface.

Industrial interest towards thin film solar cells is increased in recent years also in view of the high conversion efficiency reached so far. A record 16.5% conversion efficiency has been reported (see X. Wu et al., 17^{th} European Photovoltaic Solar Energy Conversion Conference, Munich, Germany, 22-26 Oct. 2001, II, 995-1000). Slightly lower efficiencies, but with a simplified process and a more stable back-contact have recently been obtained by some of the inventors of the present invention (N. Romeo et al., Recent progression CdTe/CdS thin film solar cells, Solar Energy, 77, (2004), 795-801). Therefore several efforts have been made to provide processes suitable for large-scale, in-line production of CdTe/CdS thin film solar cells.

A state-of-the-art report concerning this issue may be found in D. Bonnet, Thin Solid Films 361-362 (2000), 547-552. However, a number of problems still hinder the achievement of this result, in particular concerning the crucial step of the treatment of the CdTe film. As a matter of fact, most of the presently available treatment processes involve a step of CdCl₂ evaporation and in particular, as disclosed in WO03/032406, the following step of deposition of CdCl₂ is carried out at low temperature. This has the disadvantage that the CdTe film must be first cooled down to below 100° C. from the deposition temperature on the CdS film (about 500° C.) otherwise CdCl₂ vapors do not link to the CdTe crystal surface. After the low temperature deposition, the CdTe film must be heated again up to more than 400° C. in order to make a treatment in Ar atmosphere followed by a vacuum annealing to remove any residual CdCl₂. The above steps significantly affect the production costs.

As a further disadvantage, since CdCl₂ is usually available in a very fine powder form, it cannot directly be evaporated in an industrial production line, as the finest grains would be entrained in the vapors giving rise to a locally uneven deposition. For this reason CdCl₂ powder must be sintered in the form of ingots before evaporation and this is a very expensive step in view of the safety precautions to be taken to carry it out.

Furthermore, in general, CdCl₂ handling and storage has several drawbacks. CdCl₂ has a relatively low evaporation temperature (about 500° C. in air) and can be dangerous in case of fire when stored in large quantity, as required in a large-scale production plant, due to Cd release, which is highly noxious. Moreover, due to the high water solubility of CdCl₂, very severe measures have to be taken to avoid any environmental pollution and health damage.

### OBJECT AND SUMMARY OF THE INVENTION

It is the main object of the present invention to provide a process suitable for a large-scale production of stable and efficient CdTe/CdS thin film solar cells, or more generally ZnₓCd₁₋ₓS/CdTe_{y}S_{1-y} thin film solar cells as defined above, in which the production costs are reduced with respect to the known processes.

A particular object of the present invention is to provide a process of the above mentioned type in which the activation treatment of the CdTe film is conducted in such a way as not to require the use of CdCl₂.

A further object of the present invention is to provide a process of the above mentioned type, in which the step of treatment of the CdTe film is simplified with respect to the known processes.

A further object of the present invention is to provide a stable, efficient and relatively low-cost CdTe/CdS thin film solar cell.

The above object are achieved with the process for the large scale production of CdTe/CdS thin film solar cells, the main features of which are set forth in claim 1.

According to an important aspect of the invention, the activation treatment of the CdTe film is carried out by introducing a CdTe/CdS cell in a vacuum chamber wherein a chlorine-containing inert gas is fed and raising the temperature of the cell supporting substrate to 380-420° C. In this condition chlorine is released which reacts with CdTe producing TeCl₂ and CdCl₂. After some minutes vacuum is applied again leaving the cell at high temperature in such a way to cause any CdCl₂ residue formed during the treatment to evaporate from the cell surface. Thanks to the chlorine action the smallest, more instable CdTe grains are carried in vapor phase and are then recrystallized into larger, more stable grains.

According to a particular aspect of the invention the chlorine-containing inert gas is selected from chlorofluorocarbons and hydrochlorofluorocarbons products.

Further features of the process according to the invention are set forth in the dependent claims.

### BRIEF DESCRIPTION OF THE DRAWINGS

Further features and advantages of the process for large-scale production of CdTe/CdS thin film solar cells according to the present invention will be apparent from the following description of a preferred embodiment made with reference to the attached drawings, wherein:

FIG. 1 is a schematic representation of the film sequence of the CdTe/CdS thin film solar cells according to the invention;

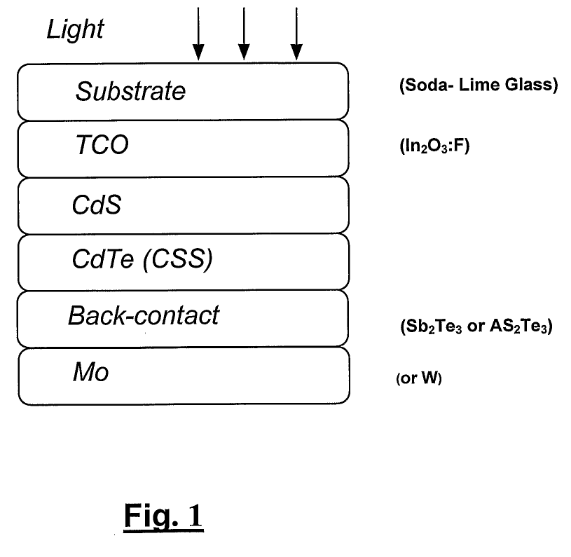

FIG. 2 is a schematic diagram of the process according to the invention —FIG. 3 shows the morphology of an untreated CdTe film deposited by high vacuum evaporation;

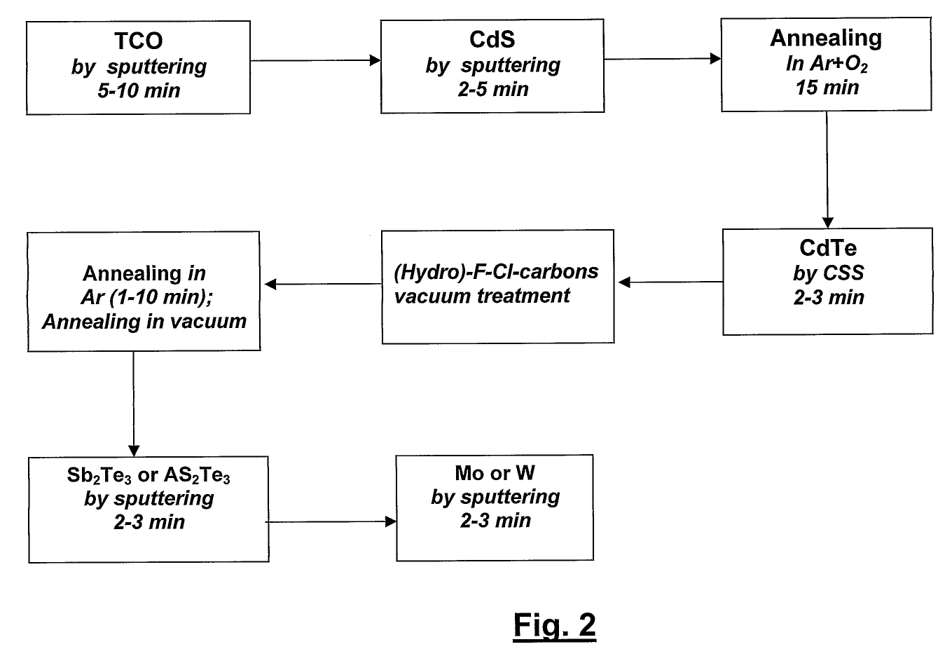

FIG. 4 shows the morphology of the film of FIG. 3 after treatment according to the invention.

### DESCRIPTION OF AN EMBODIMENT OF THE INVENTION

With reference to the figures, the CdTe/CdS solar cells produced with the process according to the invention comprise five layers deposited in a sequence on a transparent base layer or substrate and consisting of a 300-500 nm thick layer of a transparent conducting oxide (TCO), a 80-200 nm thick layer of CdS deposited on top of the TCO layer, a 4-12 μm thick layer of CdTe on top of the CdS layer and a back contact layer formed by at least 100 nm thick layer of SB₂Te₃ and 100 nm thick layer of Mo. In particular, the transparent base substrate consists of soda-lime glass and the transparent conducting oxide is fluorine-doped (In₂O₃:F).

TCO layer consists of In₂O₃, which is doped with fluorine during the growth. The In₂O₃ target, differently from ITO, does not form any noodle. A very low resistivity is obtained by introducing in the sputtering chamber a small amount of fluorine in the form of a gaseous fluoroalkyle compound such as CHF₃ and a small amount of H₂ in the form of a mixture with an inert gas such as a Ar+H₂ mixture, in which H₂ is 20% in respect to Ar. A typical example is a 500 nm film of In₂O₃ deposited with a deposition rate higher than 10 Å/sec at a substrate temperature of 500° C., with an Ar flow-rate of 200 scam, a CHF₃ flow-rate of 5 scam and an Ar+H₂ flow-rate of 20 sccm. In this way, the reactive sputtering gas is composed by Ar containing 2.5 vol. % of CHF₃ and 1.8 vol. % of H₂. This film exhibits a sheet resistance of 5Ω/_{square}, a resistivity of 2.5×10⁻⁴ Ωcm and a transparency higher than 85% in the wavelength range of 400-800 nm. Another characteristic of this film is its good stability and the ability to stop Na diffusion from the soda-lime glass. This has been demonstrated by making CdTe/CdS solar cells on top of this type of TCO which have shown to be very stable even if heated up to 180° C. when illuminated by “ten suns” for several hours.

After deposition of the CdS film and CdTe film in the known way by sputtering or close-spaced sublimation, according to the invention the CdTe film surface is treated with a chlorine-containing inert gas in the following way.

A CdTe/CdS cell prepared as described above is placed in a vacuum chamber to which 10-30 mbar and preferably 15-25 mbar of an inert gas containing Chlorine and 100-500 mbar of Argon are admitted. The cell supporting substrate is then heated to a temperature of 380-420° C. for 5 minutes. In this condition the released Chlorine reacts with solid surface CdTe to produce TeCl₂ and CdCl₂ according to the following reaction:

CdTe (solid)+2Cl₂ (gas)→TeCl₂ (gas)+CdCl₂(gas).

After this treatment vacuum is applied in the vacuum chamber, while the cell temperature is left high for few minutes in such a way to cause any residue CdCl₂ formed during the treatment to evaporate from the cell surface.

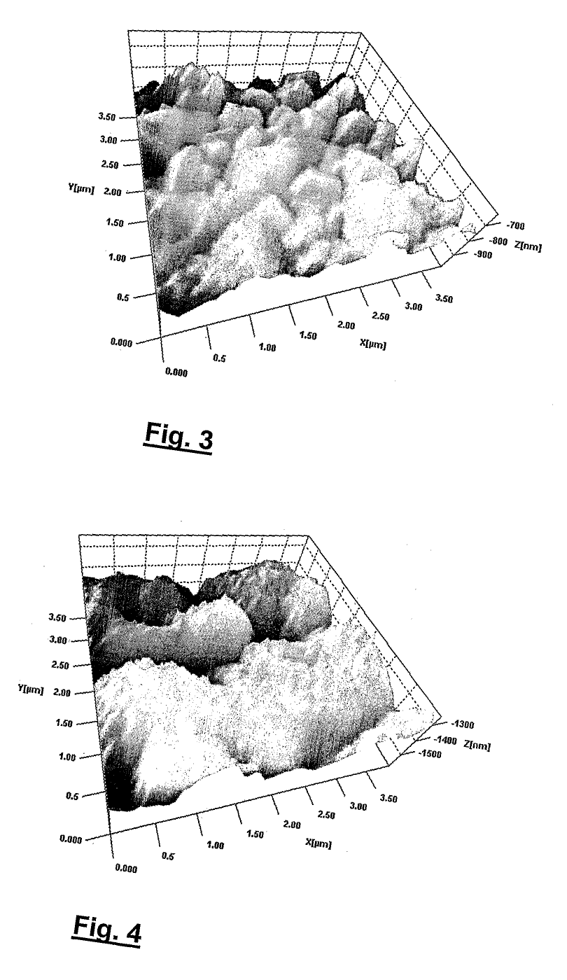

During this process the smallest and more unstable CdTe grains are vaporized and, when they recrystallize, larger, more stable CdTe grains are formed. The effect is very evident when CdTe is deposited by high vacuum evaporation in view of the fact that the average grain size is lower than one micron. This can be clearly seen by comparing FIGS. 3 and 4.

If treated CdTe is produced by CSS (Close-Spaced Sublimation), starting grains are larger, more than some microns, and a recrystallization of the grain edges is appreciated.

As a source of Chlorine-containing inert gas both Chlorofluorocarbons and Hydrochlorofluorocarbons may be used. These are non-flammable, non-corrosive, non-toxic and odorless gases. Even if Chlorofluorocarbons are considered dangerous for the ozone layer surrounding the Earth, they could be used in an industrial process being easily recoverable in a closed circuit plant without any pollutant immission to the atmosphere.

The above described CdTe activation process can be very easily exploited. In an industrial production line the process allows a CdCl₂ evaporation machine to be avoided, CdCl₂ being usually made available in powder form and having a relatively low sublimation temperature of about 300° C. under vacuum conditions. Furthermore, CdCl₂ is replaced by a non-toxic, non-flammable gas easily transportable in low pressure tanks. As a further advantage with respect to the prior art CdTe treatment methods, the method of the invention requires only few minutes to be carried out, this resulting in a significant reduction of the length of the production line.

According to the present invention a Te-rich surface is not needed to obtain a non-rectifying contact if the contact is made by depositing on top of CdTe film a thin layer of a highly conducting p-type semiconductors such as Sb₂Te₃ or As₂Te₃. A good not rectifying contact is obtained on a clean CdTe surface if at least 100 nm thick layer of Sb₂Te₃ or As₂Te₃ is deposited by sputtering at a substrate temperature respectively of 250-300° C. and 200-250° C. Sb₂Te₃ grows naturally p-type with a resistivity of 10⁻⁴ Ωcm, while As₂Te₃ grows p-type with a resistivity of 10⁻³ Ωcm. The contact procedure is completed by covering the low resistivity p-type semiconductor with at least 100 nm of Mo or W, as common practice in the art. A thin layer of Mo or W is needed in order to have a low sheet-resistance on the back-contact.

By following the procedure described above several solar cells have been prepared by using as a substrate a 1 inch square low-cost soda-lime glass.

A typical area of these cells is 1 cm². The finished cells are generally put under 10-20 suns for several hours at a temperature of 180° C. in the open-circuit-voltage (V_{oc}) conditions. No degradation has been notified but rather a 20% or more increase in the efficiency has been found.

The efficiency of these cells are in the range 14%-15.8% with open-circuit-voltages (V_{oc}) of 800-870 mV, short-circuit-currents (J_{sc}) of 23-26 MA/cm² and fill-factors (ff) ranging from 0.65 to 0.73.

### Example

A cell exhibiting a 15% efficiency has been prepared in the following way: a soda-lime glass has been covered by 500 nm of In₂O₃:F (fluorine-doped) deposited at 500° C. substrate temperature as described above. 100 nm of CdS have been deposited by sputtering at 300° C. substrate temperature and annealed for 15 min at 500° C. in 500 mbar of Ar containing 20% of O₂. 8 μm of CdTe have been deposited on top of CdS by CSS at a substrate temperature of 500° C. Both CdS and CdTe films are produced from a compact block source as described in WO03/032406. A treatment with HCF₂Cl has been done in an Ar atmosphere as described above. Finally a back contact has been created, without any etching, by depositing in sequence by sputtering 150 nm of Sb₂Te₃ and 150 nm of Mo.

After one hour under 10 suns at a temperature of 180° C. in open-circuit conditions the solar cell prepared in this way exhibited the following parameters:

| V_{oc} | 860 mV |
|---|---|
| J_{sc} | 25.4 mA/cm² |
| ff | 0.69 |
| efficiency | 15% |

Similar results are obtained by using CClF₃ for the treatment of CdTe films.

What is claimed is:

1. A process for large-scale production of CdTe/CdS thin film solar cells, the films being deposited as a sequence on a transparent substrate, comprising the steps of:
depositing a film of a transparent conductive oxide (TCO) on the substrate;
depositing a film of CdS on the TCO film;
depositing a film of CdTe on the CdS film;
submitting the CdTe film to an activation treatment; and
depositing a back-contract film on the treated CdTe film; wherein the activation treatment of the CdTe film comprises the following steps:
introducing the CdTe/CdS deposited on the substrate in a vacuum chamber,
heating the supporting substrate to an operating temperature of 380-420° C.,
introducing in the vacuum chamber an inert gas and a Chlorine-containing inert gas selected from Chlorofluorocarbon and Hydrochlorofluorocarbon products, whereby Chlorine released as a result of the thermal dissociation of the product reacts with solid CdTe present on the cell surface to produce TeCl₂ and CdCl₂ vapors, and
applying vacuum to the vacuum chamber, while keeping the temperature at the operating value, whereby any residual CdCl₂ is removed from the cell surface.

2. The process set forth in claim 1, wherein the inert gas is Argon.

3. The process set forth in claim 1, wherein 10-30 mbar of Chlorine-containing inert gas and 100-500 mbar of inert gas are admitted to the vacuum chamber.

4. The process set forth in claim 1, wherein the supporting substrate to the operating temperature for 1-10 minutes.

5. The process according set forth in claim 1, wherein the back-contact film is formed by a Sb₂Te₃ layer on the unetched CdTe film surface.

6. The process set forth in claim 5, wherein the Sb₂Te₃ layer is covered by a layer of Mo or W.

7. The process set forth in claim, wherein the Sb₂Te₃ layer is formed by sputtering at 250-300° C.

8. The process set forth in claim 1, wherein the back-contact film is formed by a As₂Te₃ layer covered by a layer of Mo or W.

9. The process set forth in claim 8, wherein the As₂Te₃ layer is formed by sputtering at 200-250° C.

10. The process claim 1, wherein the transparent conductive oxide is In₂O₃ doped with fluorine.

11. The process set forth in claim 10, wherein the TCO layer is formed by sputtering in an inert gas atmosphere containing hydrogen and a gaseous fluoroalkyle compound.

12. The process set forth in claim 11, wherein a mixture of Ar and hydrogen is used, which comprises between about 1% and about 3% hydrogen by volume and wherein the fluoroalkyle compound is CHF₃.

13. A CdTe/CdS thin film solar cell, wherein the film is deposited as a sequence on a transparent substrate, comprising the steps of:
depositing a film of a transparent conductive oxide (TCO) on the substrate;
depositing a film of CdS on the TCO film;
depositing a film of CdTe on the CdS film;
submitting the CdTe film to an activation treatment; and
depositing a back-contract film on the treated CdTe film; wherein the activation treatment of the CdTe film comprises the steps of:
introducing the CdTe/CdS deposited on the substrate in a vacuum chamber.
heating the supporting substrate to an operating temperature of 380-420° C.
introducing in the vacuum chamber an inert gas and a Chlorine-containing
inert gas selected from Chlorofluorocarbon and Hydrochlorofluorocarbon products, whereby Chlorine released as a result of the thermal dissociation of the product reacts with solid CdTe present on the cell surface to produce TeCl₂ and CdCl₂ vapors, and
applying vacuum to the vacuum chamber, while keeping the temperature at the operating value, whereby any residual CdCl₂ is removed from the cell surface.

14. The solar cell set forth in claim 13, further comprising a transparent substrate on which a layer of a transparent conductive oxide (TCO) is deposited, a CdS layer deposited on the TCO layer, a CdTe layer deposited on the CdS layer and a back-contact layer on the CdTe layer, wherein the back-contact layer is deposited on an unetched surface of the CdTe film treated with a Chlorine-containing inert gas selected from Chlorofluorocarbon and Hydrochlorofluorocarbon products.
